(19) United States
(12) Patent Application Publication
(10) Pub. No.: US 2012/0100656 A1
(43) Pub. Date: Apr. 26, 2012

(54) METHOD FOR MAKING A SOLID STATE SEMICONDUCTOR DEVICE

(75) Inventors: SHIH-CHENG HUANG, Hukou (TW); PO-MIN TU, Hukou (TW); SHUN-KUEI YANG, Hukou (TW); CHIA-HUNG HUANG, Hukou (TW)

(73) Assignee: ADVANCED OPTOELECTRONIC TECHNOLOGY, INC., Hsinchu Hsien (TW)

(21) Appl. No.: 13/172,840

(22) Filed: Jun. 30, 2011

(30) Foreign Application Priority Data
Oct. 21, 2010 (CN) 201010513029.1

(51) Int. Cl. H01L 33/18

(52) U.S. Cl. 438/47; 257/E33.023

(57) ABSTRACT

A method for making a solid state semiconductor device includes: providing a substrate; forming a buffer layer on the substrate; forming a first epitaxial layer on the buffer layer; forming a surface-textured second epitaxial layer on the first epitaxial layer by chemical vapor deposition; and forming a solid state stacked layer structure having a PN-junction type light-emitting part on a textured surface of the second epitaxial layer.

### BACKGROUND

1. Technical Field

The present disclosure generally relates to methods for making solid state semiconductor devices, and particularly to a method for making a light emitting diode.

2. Description of Related Art

Generally, a light-emitting diode is fabricated by growing a stacked semiconductor layer structure having a PN junction type light-emitting part on a substrate. However, the lattice constant of the stacked semiconductor layer is quite different from that of the substrate. As such, high lattice mismatch between the substrate and the semiconductor layer causes defects in the stacked semiconductor layer. Thereby, lifetime is shortened and light-emitting efficiency is decreased.

Therefore, it is necessary to lower the lattice mismatch in light emitting diodes.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the disclosure.

FIG. 1 is a flow chart of a method for making a solid state semiconductor device of the present disclosure.

FIG. 2 is a schematic view of a solid state semiconductor device made by the method as illustrated in FIG. 1 of the present disclosure.

### DETAILED DESCRIPTION

Reference will now be made to the drawings to describe the present method for making a solid state semiconductor device in detail.

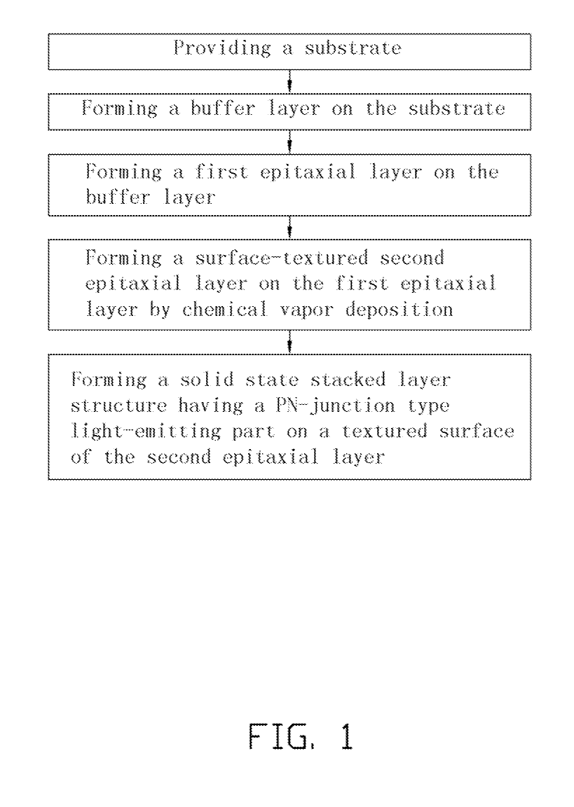

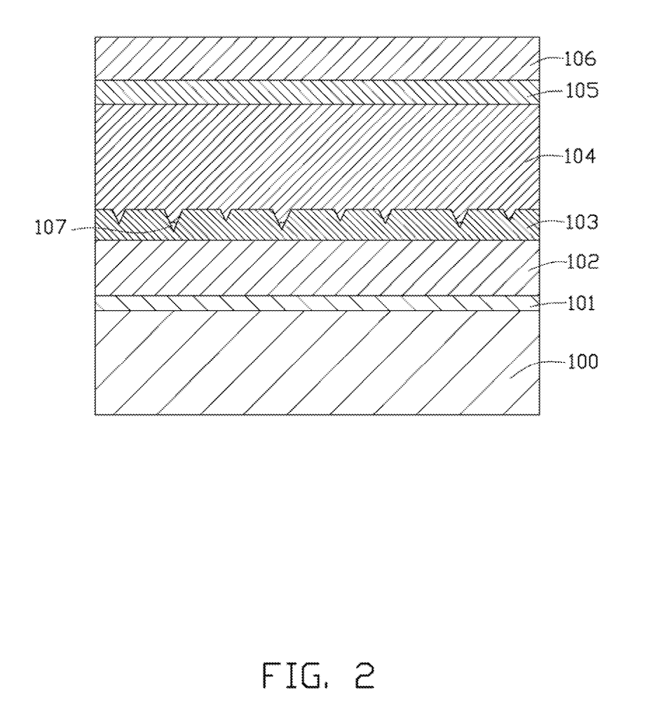

Referring to FIGS. 1 and 2, a method for making a solid state semiconductor device comprises following steps: (a) providing a substrate 100; (b) forming a buffer layer 101 on the substrate 100; (c) forming a first epitaxial layer 102 on the buffer layer 101; (d) forming a surface-textured second epitaxial layer 103 on the first epitaxial layer 102 by chemical vapor deposition; and (e) forming a solid state stacked layer structure having a PN-junction type light-emitting part on a textured surface of the second epitaxial layer 103.

In step (a), the substrate 100 is provided and configured for growing epitaxial layers thereon. The material of the substrate 100 can be sapphire, gallium nitride (GaN), aluminum nitride (AlN), gallium aluminum nitride (AlGaN), silicon carbide (SiC) or silicon. In this embodiment, the substrate 100 is made of sapphire.

In step (b), the buffer layer 101 is formed on a top surface of the substrate 100, to lower/eliminate the lattice mismatch of the solid state semiconductor device. The buffer layer 101 can be a semiconductor layer of group III-V compounds. In this embodiment, the buffer layer 101 is a semiconductor layer of group III nitrides.

In step (c), the first epitaxial layer 102 is a semiconductor layer of group III nitrides, and is formed on a top surface of the buffer layer 101.

In step (d), the second epitaxial layer 103 is made of a polycrystalline material with hexagonal system structure, for example GaN. The second epitaxial layer 103 is grown on the first epitaxial layer 102 by chemical vapor deposition (CVD) at 750-950 degrees centigrade, preferably at 800-900 degrees centigrade. In this embodiment, the second epitaxial layer 103 is grown on the first epitaxial layer 102 by metal-organic chemical vapor deposition (MOCVD). A top surface of the second epitaxial layer 103 is textured.

Due to low migration speed of atoms under above disclosed temperature range, a plurality of pits 107 is formed in the textured top surface of the second epitaxial layer 103 where defects exist. Due to that the second epitaxial layer 103 is a semiconductor layer of N-type gallium nitride with hexagonal system structure in this embodiment, the plurality of pits 107 each has a shape of a hexagonal pyramid.

In step (e), the solid state stacked layer structure is grown on the textured top surface of the second epitaxial layer 103. The solid state stacked layer structure is made of group III nitrides. Step (e) includes following steps: forming an n-type semiconductor layer 104 on the textured surface of the second epitaxial layer 103; forming an active layer 105 on the n-type semiconductor layer 104; and forming a p-type semiconductor layer 106 on the active layer 105. In the present method, the plurality of pits 107 formed in the second epitaxial layer 103 lowers/eliminates lattice mismatch between the second epitaxial layer 103 and the solid state stacked layer structure grown on the second epitaxial layer 103, whereby lifetime of the solid state semiconductor device is lengthened and light-emitting efficiency of the solid state semiconductor device is increased.

It is to be understood that the above-described embodiments are intended to illustrate rather than limit the disclosure. Variations may be made to the embodiments without departing from the spirit of the disclosure as claimed. The above-described embodiments illustrate the scope of the disclosure but do not restrict the scope of the disclosure.

What is claimed is:

1. A method for making a solid state semiconductor device, the method comprising steps of:
(a) providing a substrate;
(b) forming a buffer layer on the substrate;
(c) forming a first epitaxial layer on the buffer layer;
(d) forming a second epitaxial layer on the first epitaxial layer by chemical vapor deposition, the second epitaxial layer having a textured surface; and
(e) forming a PN-junction type light-emitting structure on the textured surface of the second epitaxial layer.

2. The method according claim 1, wherein step (d) is performed at 750˜950 degrees centigrade.

3. The method according claim 2, wherein step (d) is performed at 800˜900 degrees centigrade.

4. The method according claim 1, wherein step (d) is performed by metal-organic chemical vapor deposition.

5. The method according claim 1, wherein the textured surface of the second epitaxial layer comprises a plurality of hexagonal pyramid pits formed therein.

6. The method according claim 1, wherein the second epitaxial layer is made of polycrystalline materials with hexagonal system structure.

7. The method according claim 1, wherein the second epitaxial layer is a semiconductor layer of gallium nitride.

8. The method according claim 1, wherein the material of the substrate is selected from a group consisting of sapphire, gallium nitride, aluminum nitride, gallium aluminum nitride, silicon carbide and silicon.

9. The method according claim 1, wherein the buffer layer is a semiconductor layer of group III nitrides.

10. The method according claim 1, wherein step (e) comprises:
forming a n-type semiconductor layer of group III nitride on the textured surface of the second epitaxial layer;
forming an active layer of group III nitride on the n-type semiconductor layer; and
forming a p-type semiconductor layer of group III nitride on the active layer.
